(19) United States
(12) Patent Application Publication
(10) Pub. No.: US 2023/0153071 A1
(43) Pub. Date: May 18, 2023

(54) TUNABLE TRUE RANDOM NUMBER GENERATOR

(71) Applicant: International Business Machines Corporation, Armonk, NY (US)

(72) Inventor: Kangguo Cheng, Schenectady, NY (US)

(21) Appl. No.: 17/529,215

(22) Filed: Nov. 17, 2021

(51) Int. Cl. G06F 7/58; H03K 3/84; G11C 13/00

(52) U.S. Cl. CPC G06F 7/588; G11C 13/0002; H03K 3/84

(57) ABSTRACT

A tunable true random number generator (TTRNG) apparatus includes a clock pulse source; a logic voltage source; an output terminal; a ground terminal; and a plurality of transistors that are connected between the clock pulse source, the logic voltage source, the output terminal, and the ground terminal. Also included are resistive memory cells that are connected with the plurality of transistors and at least one of the logic voltage source and the ground terminal. The plurality of transistors are connected such that, at each clock pulse, the plurality of transistors deliver either logic voltage “1” or ground voltage “0” to the output terminal. The resistive memory cells are connected such that a ones probability of the plurality of transistors delivering “1” to the output terminal can be adjusted by changing the resistances of the resistive memory cells.

### BACKGROUND

The present invention relates to the electrical, electronic, and computer arts, and more specifically, to generation of random numbers.

Random numbers are used in a variety of computer applications, such as security key generation for cryptography, statistical simulation (classically, Monte-Carlo simulations) for various kinds of physical models (e.g., electronic circuit design, weather prediction, and fusion reactor design), and the like. Software-based pseudo-random number generators (PRNGs) are widely used. However, PRNGs do not provide truly random numbers due to the deterministic nature of the software programming.

Conventional hardware True Random Number Generators (TRNGs) use entropy from natural sources such as thermal fluctuation and flicker noise, making them less vulnerable to attack. Such generators use a pair of semiconductor devices (e.g., a pair of cross-coupled inverters, or a pair of ring oscillators) that are connected to an output terminal and interact to produce a high or low voltage value at the output terminal, in time with a logic clock pulse. The pair of devices are designed to have matching device characteristics to avoid biasing the output stream towards logic “1” (high voltage) or “0” (low voltage). However, inherent fabrication process variation causes intrinsic device mismatching. As a result, TRNGs as fabricated are not truly random. Furthermore, during the lifetime of TRNGs, the characteristics of TRNG devices may change due to wear-out. The wearing-out of the transistors is not uniform. As a result of at least these two factors, TRNGs may be skewed by device mismatch.

### SUMMARY

Principles of the invention provide techniques for a tunable true random number generator. In one aspect, an exemplary method for tuning a true random number generator (TRNG) includes, producing a stream of high and low bits at a node of the TRNG by repeatedly: forcing a pair of cross-coupled inverters to a meta-stable voltage state by connecting the cross-coupled inverters to a forcing voltage, wherein the node of the TRNG is a node of the cross-coupled inverters; and producing a random bit at the node of the TRNG by exposing the cross-coupled inverters to a random noise while removing the forcing voltage, such that the node returns to one of two stable voltages. The method also includes, estimating randomness of the stream at a tuning interval; comparing the estimate of randomness to a specification; and in response to the estimate of randomness failing the specification, tuning the TRNG by adjusting a resistance of at least one memory cell connected with the cross-coupled inverters.

According to another aspect, a tunable true random number generator (TTRNG) includes a clock pulse source; a logic voltage source V_{DD}; and a pair of cross-coupled inverters, that each have a p-type field effect transistor (PFET) and an n-type field effect transistor (NFET). In each inverter, the source of the PFET is connected to the drain of the NFET at an inverter output terminal, the drain of the PFET is connected to the logic voltage source, the source of the NFET is connected to the ground terminal, and the inverter output terminal is connected to gates of the other inverter’s PFET and NFET. The TTRNG also includes a control transistor and a plurality of resistive memories. The control transistor is connected to the cross-coupled inverters and to the clock pulse source such that at least one of the inverter output terminals goes to ground voltage on a high clock pulse and at least one of the inverter output terminals goes to logic voltage source on a low clock pulse. The resistive memories are operatively connected with the pair of cross-coupled inverters such that changing the resistance of one of the plurality of resistive memories increases a ones probability of settling a corresponding one of the inverter output terminals to the high voltage state while changing the resistance of another of the plurality of resistive memories decreases the ones probability.

According to another aspect, an exemplary tunable true random number generator (TTRNG) apparatus includes a clock pulse source; a logic voltage source V_{DD}; an output terminal; a ground terminal; a plurality of transistors that are connected between the clock pulse source, the logic voltage source, the output terminal, and the ground terminal; and resistive memory cells, that are connected with the plurality of transistors and at least one of the logic voltage source and the ground terminal. The plurality of transistors are connected such that, at each clock pulse, the plurality of transistors deliver either logic voltage “1” or ground voltage “0” to the output terminal. The resistive memory cells are connected such that a ones probability of the plurality of transistors delivering “1” to the output terminal can be adjusted by changing the resistances of the resistive memory cells.

In view of the foregoing, techniques of the present invention can provide substantial beneficial technical effects. For example, one or more embodiments provide one or more of:
Simple and efficient monitoring of randomness of a TRNG.
Simple and efficient mitigation of bias in a TRNG, in response to monitored randomness falling below a desired threshold.
A tunable TRNG.
A feedback mechanism for auto-tuning a TRNG.

Some embodiments may not have these potential advantages and these potential advantages are not necessarily required of all embodiments. These and other features and advantages of the present invention will become apparent from the following detailed description of illustrative embodiments thereof, which is to be read in connection with the accompanying drawings.

### BRIEF DESCRIPTION OF THE DRAWINGS

FIG. 1 depicts a true random number generator (TRNG) that incorporates a cross-coupled inverter pair for generating random bits and a memory pair for tuning the TRNG, according to an exemplary embodiment.

FIG. 2 depicts components of an inverter.

FIG. 3 details of the components and wiring in the TRNG of FIG. 1.

FIG. 4 depicts voltages at terminals of the TRNG of FIG. 1 across a low clock pulse and a high clock pulse.

FIG. 5 depicts a memory unit that incorporates a bank of tunable resistors, which can be used in the TRNG of FIG. 1.

FIG. 6 depicts a SET voltage curve of RRAM, which can be used in the TRNG of FIG. 1.

FIG. 7 depicts another TRNG that incorporates a cross-coupled inverter pair for generating random bits and a memory pair for tuning the TRNG, according to an exemplary embodiment.

FIG. 8 depicts another TRNG that incorporates a cross-coupled inverter pair for generating random bits and a memory pair for tuning the TRNG, according to an exemplary embodiment.

FIG. 9 depicts another TRNG that incorporates a cross-coupled inverter pair for generating random bits and a memory pair for tuning the TRNG, according to an exemplary embodiment.

FIG. 10 depicts voltages at terminals of the TRNG of FIG. 8 or FIG. 9 across a high clock pulse and a low clock pulse.

FIG. 11 depicts steps of a method for operating a TRNG, according to an exemplary embodiment.

### DETAILED DESCRIPTION

An aspect of the invention is the understanding that, because true random number generators (TRNGs), as manufactured and operated, do not match their ideal designed characteristics, fine-tuning “knobs” or devices can be provided to mitigate stochastic bias produced by mismatch between device pairs within a TRNG.

Accordingly, embodiments of the invention provide methods and structures for forming a true random number generator (TRNG) that is tunable by adjusting the resistances of memory cells, such as resistive memory (RRAM) or phase change memory (PCM). In one or more embodiments, a tunable TRNG incorporates a pair of cross-coupled inverters, with the adjustable memory cells connected between the cross-coupled inverters and ground, to control the rate at which voltage decays from each terminal of the TRNG.

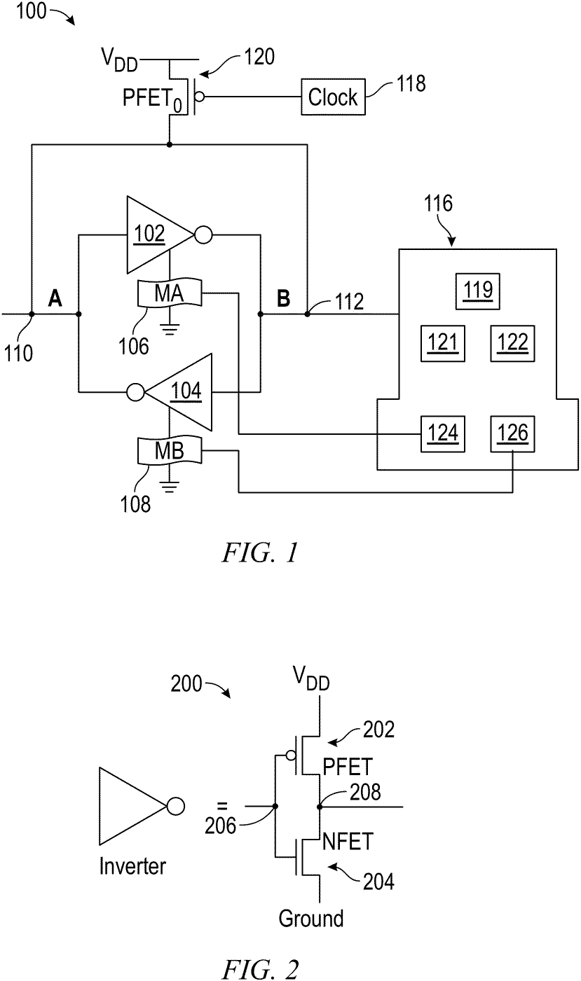

FIG. 1 depicts a TRNG 100 that incorporates a cross-coupled inverter pair 102, 104 for generating random bits, and a memory pair M_{A} 106 and M_{B} 108 for tuning the TRNG. As mentioned, the memories M_{A} and M_{B} can incorporate, for example, tunable resistors, such as resistive memory (RRAM) or phase change memory (PCM), Ferroelectric memory, conductive bridge memory, ionic thin film memristors, molecular memristors, resonant tunneling diode memristors, spintronic memristors, and spin torque transfer memristors are other examples of tunable resistors that can be utilized in one or more embodiments. M_{A} 106 is connected between the inverter 102 and ground; M_{B} 108 is connected between the inverter 104 and ground. Inverter output terminal A 110 is an internal or hidden terminal. Inverter output terminal B 112 is the TRNG output terminal where the TRNG 100 renders either high voltage (“1”) or low voltage (“0”) at each logic clock high pulse. As mentioned above, each of M_{A} 106 and M_{B} 108 can be adjusted to balance the electrical performance of the paired inverters. Inverter output terminal B 112 (the output terminal of TRNG 100) is connected to external circuitry 116. A clock source 118 triggers control transistor PFET₀ 120, which supplies logic voltage V_{DD} to inverter output terminals A 110 and B 112 on a low clock pulse.

FIG. 2 depicts components of an exemplary inverter 200. The inverter 200 includes a PFET 202 and an NFET 204. The drain of PFET 202 is connected to logic voltage V_{DD} and the source of NFET 204 is connected to ground. An input signal supplied to terminal 206 triggers the PFET 202 when low and triggers the NFET 204 when high. Terminal 208 is connected to output. Voltage at terminal 208 is high when the input signal is low (because current flows from V_{DD} through PFET 202 to terminal 208) and is low when the input signal is high (because current flows from terminal 208 through NFET 204 to ground).

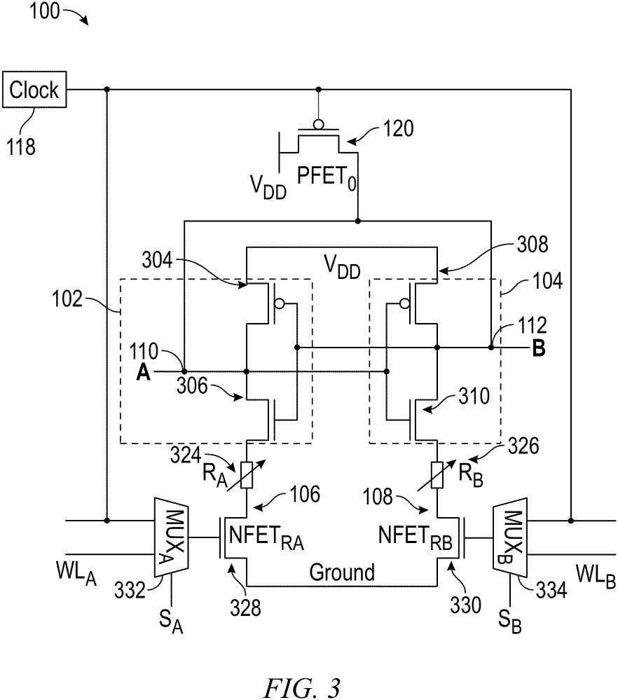

FIG. 3 depicts details of the components and wiring in the TRNG 100. The control transistor (PFET₀) 120 is provided to bias the cross-coupled inverter pair 102, 104 in a metastable state. The first inverter 102 includes PFET_{A} 304 and NFET_{A} 306. The second inverter 104 includes PFET_{B} 308 and NFET_{B} 310.

Inverter output terminal A 110 is connected to the source of PFET₀ 120, to the source of PFET_{A} 304 and the drain of NFET_{A} 306, and to the gates of PFET_{B} 308 and NFET_{B} 310.

Inverter output terminal B 112 is connected to the source of PFET₀ 120, to the source of PFET_{B} 308 and the drain of NFET_{B} 310, and to the gates of PFET_{A} 304 and NFET_{A} 306. In one or more embodiments, terminal B 112 is connected to external circuitry 116 as the output terminal of the TRNG. In other embodiments, terminal A 110 could be so connected.

M_{A} 106 and M_{B} 108 each are connected from the respective NFET_{A} or NFET_{B} to ground. Each of M_{A} or M_{B} includes a tunable resistor R_{A} 324 or R_{B} 326, respectively, and a corresponding NFET_{RA} 328 or NFET_{RB} 330.

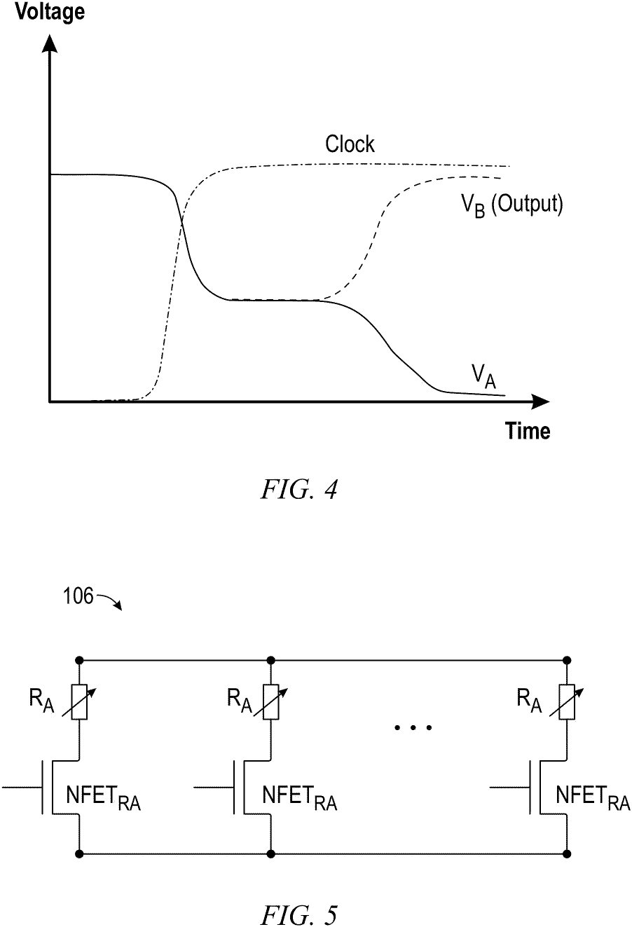

FIG. 4 depicts the voltage at terminals A and B of the TRNG 100, across a low clock pulse and a high clock pulse. The general operation of this balanced and cross-coupled inverter pair 102, 104 is that on a low clock pulse, PFET₀ 120 turns on and delivers logic voltage V_{DD} to both the inverter output terminal A 110 and the output terminal B 112, forcing them both to a meta-stable high voltage state. The logic voltage keeps PFET_{A} 120 and PFET_{B} 308 in their OFF conditions and keeps NFET_{A} 306 and NFET_{B} 310 in their ON conditions. However, the low clock pulse is applied to the gates of NFET_{RA}, and NFET_{RB} through the multiplexers MUX_{A} and MUX_{B}, leaving NFET_{RA} and NFET_{RB} in their OFF conditions so that there is no current through R_{A} and R_{B}.

On a high clock pulse, PFET₀ 120 turns OFF. NFET_{RA} and NFET_{RB} turn ON. Voltage at both terminal A 110 and terminal B 112 attempts to return to a stable state (either A=1 / B=0, or A=0 / B=1), based on the cross-coupling of output from each inverter 102, 104 to the trigger of the other inverter. The cross-coupling has a feedback characteristic such that as one inverter’s output terminal voltage drops, the other inverter’s PFET will become more conductive, the other inverter’s output terminal voltage will rise, and the first inverter’s PFET will become less conductive, further driving down the voltage of the first inverter’s output terminal. If the two inverters were perfectly matched, they would not settle. Practically, whichever inverter has a more conductive path from terminal to ground, and/or a less conductive path from logic voltage source to terminal, will win the race to the bottom. Random environmental noise (e.g., temperature variance, cosmic rays, visible light) would unbalance even perfectly matched inverters so that the TRNG prefers one of the two stable states, either A=1 / B=0, or A=0 / B=1. Additionally, the TRNG as built is imbalanced by the load of external circuitry (additional paths to ground) connected to terminal A 110 or to terminal B 112 as the TRNG output terminal. In one or more embodiments, as-built imbalance can be mitigated by presetting the resistances of M_{A} 106 and M_{B} 108.

Thus, with a series of clock pulses, a stream of putatively random bits are generated. Output terminal B 112 provides one high bit or one low bit on each clock high pulse. The ordinary skilled worker will appreciate that the clock signal would return to low soon after the right edge of FIG. 4, thereby demarking the bit.

As mentioned, TRNGs as fabricated are not truly random and the components of TRNGs do not wear uniformly. Therefore, practical TRNGs are only putatively random but actually tend to be biased toward 1 or 0 in their output. Accordingly, aspects of the invention provide structures and methods to monitor the randomness of TRNGs and to tune TRNGs back toward a 50/50 probability of 1 or 0 in response to detecting a shortfall of randomness. In one or more embodiments, overcontrol is avoided by carrying out the monitoring and the tuning on a relatively long time frame, e.g., on the order of 1x10⁶ clock pulses. In some embodiments, the tuning of TRNG is carried out when the probability of a logic “1” or “0” is greater than 51% or less than 49%, more preferably greater than 50.5% or less than 49.5%. The periodicity of the tuning steps depends on unbalancing (a.k.a., mismatch) between two inverters as well as the wear-out rates of the inverters. Typically, a major tuning is performed right after the TRNG is fabricated, to compensate for fabrication process-related inverter mismatching. Tuning can also be performed at the beginning of each time when powering up the TRNG.

Referring again to FIG. 1, the external circuitry 116 includes a randomness monitor 119 and a tuning controller 121 in addition to user circuitry 122 that implements an end task of any type using the output of the TRNG.

In one or more embodiments, the randomness monitor 119 is a single adder (or counter) circuit that totals the number of “1” signals produced from output terminal B 112 during a tuning period. In one or more other embodiments, the randomness monitor 119 is a capacitor that accumulates charge based on how many “1” signals are produced from terminal B during a tuning period. In certain aspects of the invention, it may be advantageous to use a capacitor as the randomness monitor because the analog behavior of the capacitor and its tendency to trickle discharge (e.g., via tunneling effects) can introduce a certain amount of additional entropy into the tuning method, as further discussed below. In one or more embodiments, the randomness monitor 119 is implemented in software that receives the sequence of signals from the output terminal B 112 during each tuning period.

In various embodiments, the randomness monitor 119 provides a signal to the tuning controller 121, at the periodicity of the tuning procedure (e.g., once in 1x10⁶ clock cycles). The signal may be a digital signal (e.g., the total number of “1” bits produced from the output terminal B 112 during the tuning period) or an analog signal (e.g., a capacitor voltage). A digital signal will be precisely related to the bits streamed from the output terminal B, whereas an analog signal such as a capacitor voltage will have a somewhat imprecise and unpredictable relationship to the output of terminal B.

In one or more embodiments, the tuning controller 121 is a pair of comparator circuits 124, 126. One of the comparators (a “low” comparator) 124 triggers to generate a switching signal S_{A} when the signal from the randomness monitor 119 is less than a low threshold, indicating that during the periodicity of tuning somewhat fewer than one half of the random bits have been “1;” that is, a “ones probability” of the TRNG is less than one half. The other comparator (a “high” comparator) 126 triggers to generate a switching signal S_{B} when the signal from the randomness monitor 119 is more than a high threshold, indicating that during the periodicity of tuning somewhat more than one half of the random bits have been “1;” that is, the ones probability is more than one half. Additional circuitry in the tuning controller 121 generates a tuning pulse sequence WL in response to the amount by which the signal from the randomness monitor 119 exceeds one of the thresholds. In one or more embodiments, a total high duration of the tuning pulse sequence WL is proportional to the amount of excess in the signal from the randomness monitor 119.

In one or more embodiments, the user circuitry 122 is a pseudo-random number generator (PRNG) that samples the bit stream from output terminal B 112 as its seed.

Referring back to FIG. 3, M_{A} 106 and M_{B} 108 each include the tunable resistor R_{A} 324 and R_{B} 326, respectively, and the corresponding NFET_{RA} 328 or NFET_{RB} 330 that connects resistor R_{A} 324 or R_{B} 326 to ground. The outputs of respective multiplexers MUX_{A} 332 and MUX_{B} 334 can trigger the NFETs 328, 330 to conduct.

In one or more embodiments, the low comparator 124 (for example) is connected to provide switching signal S_{A} to MUX_{A} 332. On the other hand, the high comparator 126 is connected to provide switching signal S_{B} to MUX_{B} 334. Comparators 124, 126 are shown in FIG. 1 but not in FIG. 3.

During normal operation, when S_{A} is low, MUX_{A} transmits the clock pulse to NFET_{RA}. The result is that when the clock is low, although PFET₀ 120 and NFET_{A} 306 provide the logic voltage V_{DD} to R_{A} 324, NFET_{RA} 328 is not turned ON, so there is no path for current through R_{A} 324. On the other hand, when the clock is high, NFET_{RA} 328 is turned ON so that voltage from inverter output terminal A 110 can dissipate to ground through R_{A} 324. A trickle current through R_{A} 324 on a high clock pulse does not “set” or adjust the resistance of R_{A} 324. Similarly, during normal operation S_{B} also is low so that MUX_{B} transmits the clock pulse to NFET_{RB} with similar results for R_{B}.

On the other hand, when the comparator 124 indicates that the ones probability is out of a specification (e.g., less than 49.5%), S_{A} is set high. This means that MUX_{A} does not transmit the clock pulse, but instead transmits the tuning signal WL_{A} to NFET_{RA}. Similarly, when the comparator 126 indicates that the ones probability is out of a specification (e.g., greater than 50.5%) S_{B} is set high so that MUX_{B} does not transmit the clock pulse, but instead transmits the tuning signal WL_{B} to NFET_{RB}. In some embodiments, both the word line (tuning) signal WL_{A} and the word line (tuning) signal WL_{B} are essentially the same tuning signal WL that is generated by the tuning controller 121 in response to excess of the randomness monitoring signal, just directed to different components according to which comparator 124, 126 has been turned ON. In other embodiments, the word line (tuning) signal WL_{A} and the word line (tuning) signal WL_{B} each has its dedicated signal line. Also note that, instead of using two comparators 124 and 126, one can use a single comparator. A tuning signal can be sent to the word line (tuning) signal WL_{A} or the word line (tuning) signal WL_{B}, depending on whether the ones probability falls below a lower threshold (e.g., 49.5%) or rises above an upper threshold (e.g., 50.5%).

Fine-tuning the TRNG 100 is done during low clock pulses, when terminal A 110 and terminal B 112 are biased to logic voltage, with MUX_{A} 332 or MUX_{B} 334 turned ON by respective switching signal S_{A} or S_{B}, so that the respective tuning signal WL_{A} or WL_{B} can trigger NFET_{RA} 328 or NFET_{RB} 330 to let relatively large current flow through R_{A} 324 or R_{B} 326 from their respective TRNG terminal to ground. The flow of current during tuning is sufficient to adjust the resistance of R_{A} 324 or R_{B} 326. The amount of resistance adjustment on the tunable resistor signal R_{A} and R_{B}, can be controlled by the amplitude and/or duration of pulses applied to the tuning signal WL_{A} and WL_{B}. In some embodiments, a single pulse with appropriate amplitude and duration (e.g., a pulse with 3-volt amplitude, 1 micron second duration, and 50% duty cycle) is sufficient to achieve desired resistance adjustment. In other embodiments, a series of pulses can be used during find-tuning. Typically, the amplitude of the clock is lower than the amplitude of the pulse applied on the tuning signal WL_{A} or WL_{B} so that no resistance change on the tunable resistors tuning signal R_{A} 324 or R_{B} 326 during random number generation.

Thus, the randomness monitor 119 and the tuning controller 121, in combination with MUX_{A} 332, MUX_{B} 334, NFET_{RA} 328, and NFET_{RB} 330, constitute an exemplary means for tuning the TRNG 100 to adjust the ones probability toward one half by changing the resistance of one or both of the adjustable resistors R_{A} 324 and R_{B} 326. Equivalent means will be apparent to an ordinary skilled worker. For example, one could design a circuit to measure and adjust zeroes probability rather than ones probability (i.e. subtracting ones probability from 1, or similar expedients). However, the result of such a circuit still would be to adjust ones probability as well, since the ones and zeroes probabilities are inverse of each other in a binary system.

For example, R_{A} and R_{B} can be phase change memory (PCM) in a partial SET state. PCM resistance can be gradually reduced by the SET operation (passing electrical current through the PCM). Conversely, PCM resistance can be increased by RESET operation (passing electrical current through the PCM to melt the PCM and then to quench). Alternatively, resistive memory (RRAM) can be used. RRAM resistance can be gradually reduced by RESET operation.

How much the resistance is changed depends on the amplitude of the tuning signal and total high duration of the tuning signal. More pulses in the tuning signal means a greater change in resistance. In one or more embodiments, only one of the tunable resistors is tuned at a time. In other embodiments, one or both of the tunable resistors can be tuned during a single tuning sequence.

Generally, reducing the resistance of R_{A} or R_{B} tends to bias the corresponding terminal A or terminal B toward a “0” stable state. Increasing the resistance of R_{A} or R_{B} tends to bias the corresponding terminal A or terminal B toward a “1” stable state.

Although FIG. 3 shows only single adjustable resistors R_{A}, R_{B}, one or each of the memories M_{A} or M_{B} actually can be composed of multiple components as shown in FIG. 5, where M_{A} 106 includes several tunable resistors and respective NFETs arranged in parallel. Parallel arrangement of multiple components permits finer gradations of total resistance by adjusting one or more of the parallel resistors at a time. In one or more embodiments, PCM and RRAM could be arranged in parallel so that resistance can be adjusted upward or downward by directing the tuning signal to selected NFETs within the parallel array.

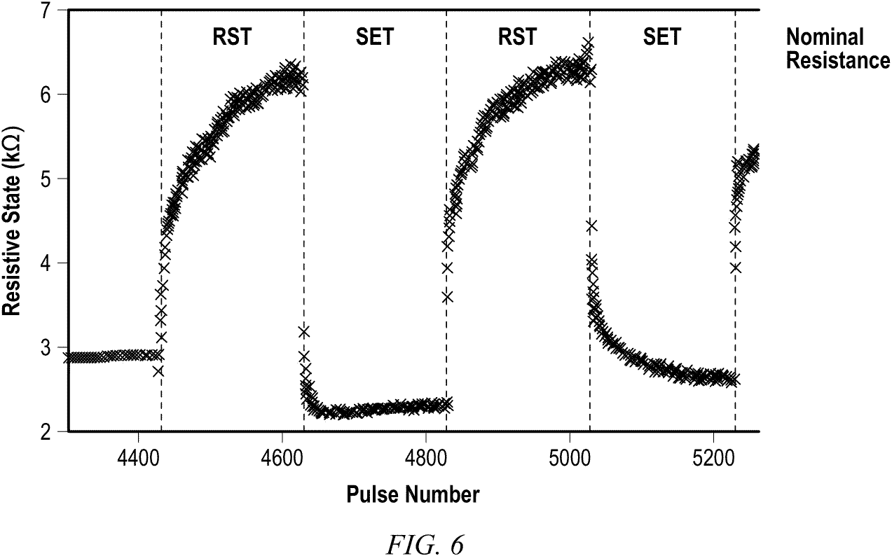

FIG. 6 depicts a graph of RRAM resistance according to a sequence of SET (low forward voltage) and RESET(RST) (high reverse voltage) pulses. Note that for an initial resistance of about 5000 ohm, each SET pulse raises resistance by about 10 ohm. Although resistance approaches a maximum limit, about one hundred adjustments can be made before responsiveness begins to diminish. Assuming that each FET of an inverter has an on-resistance of about 4000 ohm, and that the RRAM (as shown in FIG. 6 as an example) is capable of changing its resistance by about 10 ohm per pulse, then each pulse of a tuning signal can correct a mismatch down to 0.25% (10 ohm / 4000 ohm). The granularity of resistance tuning can be further reduced by connecting multiple RRAM cells in parallel (for example 10 cells) instead of a single memory cell in each inverter. This means a resistance of a group of 10 RRAM cells in parallel can be tuned 1 ohm per pulse, translating to 0.025% tunability.

Although using emerging memory alone may not completely eliminate device mismatching of a random number generator (RNG), aspects of this invention do provide a unique way to a) reduce mismatching, and b) do so dynamically, in response to real-time variations in apparent randomness of the RNG output. It should be understood that device mismatching does not need to be completely eliminated in order to attain randomness. Instead, a TRNG will perform in a “true” random fashion whenever the device mismatch is sufficiently smaller than the variations in natural sources of randomness such as thermal or electromagnetic noise. As an example, when the mismatch between the inverter pair in the TRNG is reduced to 0.5% or below, the device mismatch is sufficiently smaller than the variations in natural sources of randomness so that the TRNG produces random number bits that pass a randomness test based on the NIST (National Institute of Standards and Technology) test suite - “A Statistical Test Suite for Random and Pseudorandom Number Generators for Cryptographic Applications.”

FIG. 3 shows memory pairs connected to NFETs to fine-tune the RNG. Conversely, the memory pairs can be connected to PFETs to achieve the same goal, in a manner apparent to the ordinary skilled worker.

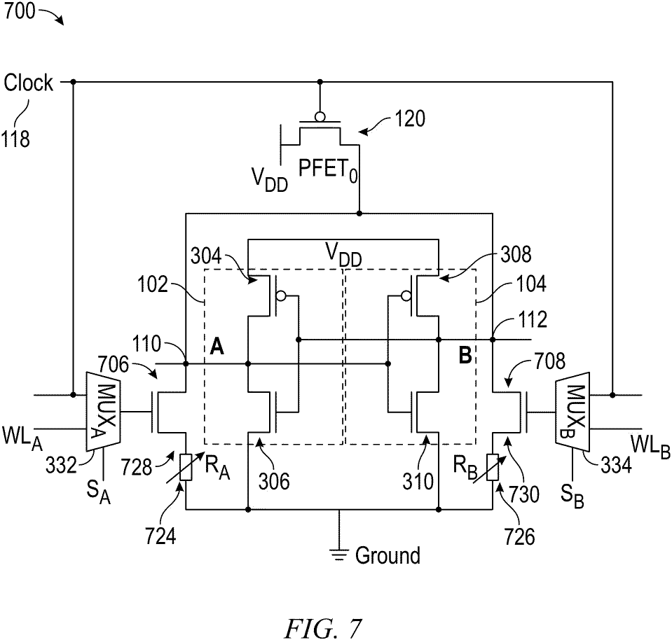

FIG. 7 depicts a different tunable TRNG 700, according to an exemplary embodiment. Many components of the TRNG 700 are similar or identical to those of the TRNG 100 (as shown in FIG. 1 and FIG. 3), are similarly arranged, and therefore are similarly numbered. However, in the TRNG 700, M_{A} 706 (including R_{A} 724 and NFET_{RA} 728) and M_{B} 708 (including R_{B} 726 and NFET_{RB} 730) are arranged in parallel to NFET_{A} 306 and NFET_{B} 310, respectively. It might be expected that, when turned ON by the high clock pulse, having M_{A} and M_{B} arranged in parallel to the respective NFETs reduces the effective resistance between terminals A and B to the ground, speeding up the rate at which the TRNG settles to its stable state. A downside to this configuration is that the tunable resistance is more susceptible to undesired programming during the normal random number generation. To avoid undesired programming during the normal random number generation, the voltage VDD in this configuration should be lower than VDD in the configuration having memories in series to NFETS.

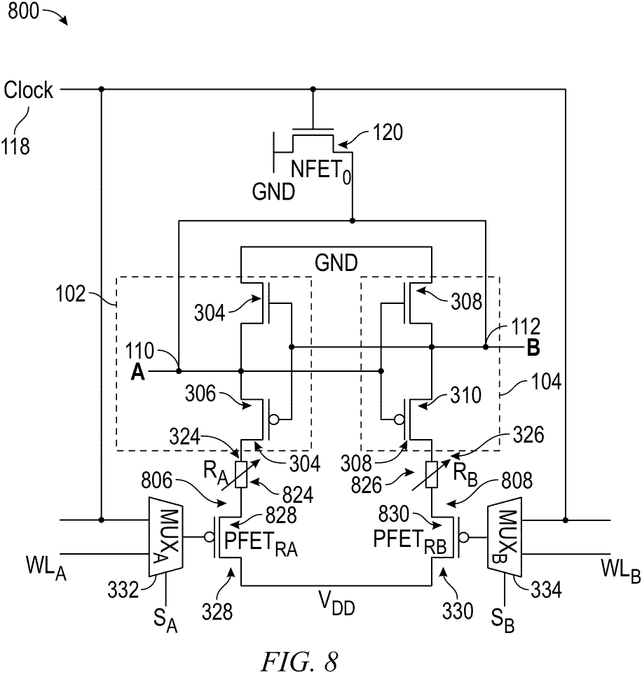

FIG. 8 depicts a different tunable TRNG 800, according to an exemplary embodiment. Many components of the TRNG 800 are similar or identical to those of the TRNGs 100 and 700, and therefore are similarly numbered, but are differently arranged. In particular, NFET₀ 820 replaces PFET₀ 120 (and is turned ON, on a HIGH clock pulse); M_{A} 806 and M_{B} 808 are connected between V_{DD} and respective PFET_{A} 304 and PFET_{B} 308; and M_{A} 806 incorporates R_{A} 824 and PFET_{RA} 828 while M_{B} 808 incorporates R_{B} 826 and PFET_{RB} 830. MUX_{A} 332 triggers PFET_{RA} 828 while MUX_{B} 334 triggers PFET_{RB} 830.

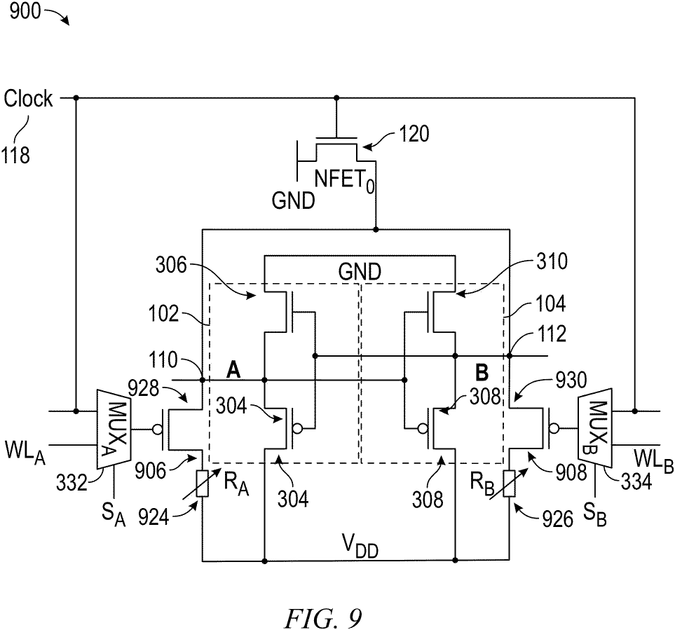

FIG. 9 depicts a different tunable TRNG 900, according to an exemplary embodiment. Many components of the TRNG 900 are similar or identical to those of the TRNGs 100, 700 and 800, and therefore are similarly numbered, but are differently arranged. In particular, in the TRNG 900, M_{A} 906 and M_{B} 908 are arranged in parallel to PFET_{A} 304 and PFET_{B} 308, respectively. M_{A} 906 incorporates R_{A} 924 and PFET_{RA} 928 while M_{B} incorporates R_{B} 926 and PFET_{RB} 930. Relative advantages of TRNGs 800 and 900 are similar to the performance and functionality tradeoffs of TRNGs 100 and 700.

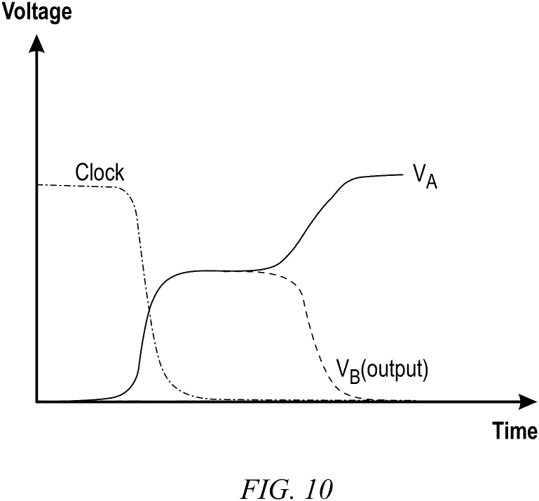

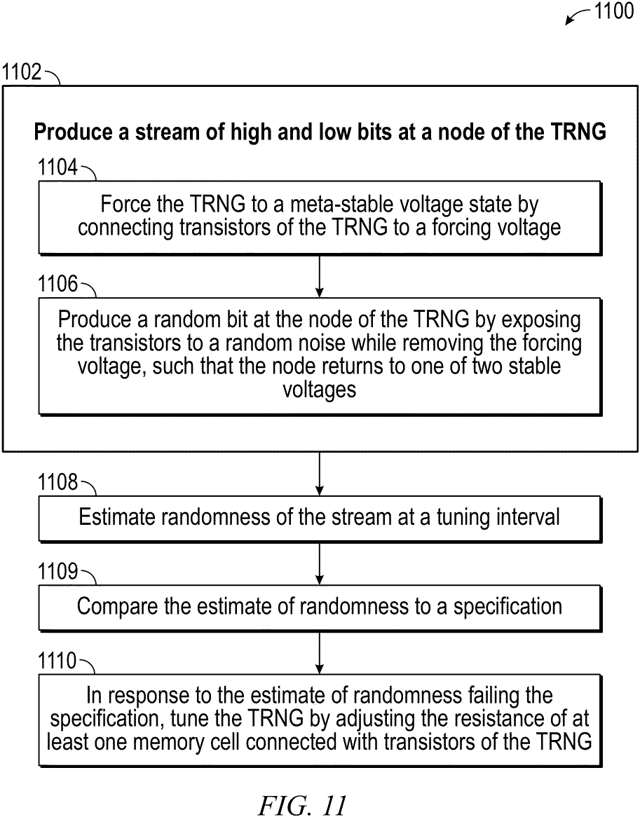

FIG. 10 depicts the voltage at terminals A and B of the TRNG 800 or 900, across a high clock pulse and a low clock pulse.

FIG. 11 depicts steps of a method 1100 for operating a TRNG, according to an exemplary embodiment. The method 1100 includes a loop 1102 for producing a stream of high and low bits at a node of the TRNG by repeatedly: at 1104, forcing the TRNG to a meta-stable voltage state by connecting transistors of the TRNG to a forcing voltage; and, at 1106, producing a random bit at the node of the TRNG by exposing the transistors of the TRNG to a random noise while removing the forcing voltage, such that the node returns to one of two stable voltages. In one or more embodiments, the TRNG may include a pair of cross-coupled inverters and the node of the TRNG may be a node of the pair of cross-coupled inverters. Then at 1108, estimate randomness of the stream at a tuning interval. For example, randomness can be estimated by accumulating a total number of high bits in an adder circuit, or by accumulating charge from each high bit in a capacitor. At 1109, compare the estimate of randomness to a specification. For example, comparing to a specification can be accomplished by comparing the adder value to a total number of high and low bits, or by comparing voltage across the capacitor to a diode voltage drop. At 1110, in response to the estimate of randomness failing the specification (e.g., the adder value is too large or too small relative to the total number of bits; the capacitor voltage is too large or too small relative to the diode voltage drop), tune the TRNG by adjusting the resistance of at least one memory cell connected with transistors of the TRNG (in one or more embodiments, transistors of the cross-coupled inverters). In one or more embodiments, the adjustment to resistance may be proportional to an amount by which the estimate of randomness fails the specification.

Given the discussion thus far, it will be appreciated that, in general terms, an exemplary tunable true random number generator (TTRNG) apparatus 100, 700, 800, or 900 includes a clock pulse source 118; a logic voltage source V_{DD}; an output terminal 112; a ground terminal; a plurality of transistors 304, 306, 308, 310 that are connected between the clock pulse source, the logic voltage source, the output terminal, and the ground terminal; and resistive memory cells 106, 108 that are connected with the plurality of transistors and at least one of the logic voltage source and the ground terminal. The plurality of transistors are connected such that, at each clock pulse, the plurality of transistors deliver either logic voltage “1” or ground voltage “0” to the output terminal. The resistive memory cells are connected such that a ones probability of the plurality of transistors delivering “1” to the output terminal can be adjusted by changing the resistances of the resistive memory cells.

In one or more embodiments, the TTRNG also includes a randomness monitor 119 that is configured to monitor the ones probability during a sequence of clock pulses; and a tuning controller 121 that is configured to adjust the ones probability for a subsequent sequence of clock pulses by changing the resistance of one or more of the resistive memory cells. In one or more embodiments, the randomness monitor includes a digital adder circuit. In one or more embodiments, the randomness monitor includes an analog capacitor. In one or more embodiments, the tuning controller includes a first comparator 124 that compares a signal from the means for monitoring the ones probability to a low threshold value; and a second comparator 126 that compares a signal from the means for monitoring the ones probability to a high threshold value.

In one or more embodiments, the plurality of transistors include a pair of cross-coupled inverters 102, 104 that have NFET sources connected to ground voltage; and a control transistor 120 that connects the NFET sources of the cross-coupled inverters to the ground voltage.

In one or more embodiments, the plurality of transistors include a pair of cross-coupled inverters 102, 104 that have PFET drains connected to logic voltage; and a control transistor 120 that connects the PFET drains to the logic voltage.

According to another aspect, a tunable true random number generator (TTRNG) 100, 700, 800, or 900 includes a clock pulse source 118; a logic voltage source V_{DD}; and a pair of cross-coupled inverters 102, 104 that each have a p-type field effect transistor (PFET) and an n-type field effect transistor (NFET). In each inverter, the source of the PFET is connected to the drain of the NFET at an inverter output terminal, the drain of the PFET is connected to the logic voltage source, the source of the NFET is connected to the ground terminal, and the inverter output terminal is connected to gates of the other inverter’s PFET and NFET. The TTRNG also includes a control transistor 120 and a plurality of resistive memories 106, 108. The control transistor is connected to the cross-coupled inverters and to the clock pulse source such that at least one of the inverter output terminals goes to ground voltage on a high clock pulse and at least one of the inverter output terminals goes to logic voltage source on a low clock pulse. The resistive memories are operatively connected with the pair of cross-coupled inverters such that changing the resistance of one of the plurality of resistive memories increases a ones probability of settling a corresponding one of the inverter output terminals to the high voltage state while changing the resistance of another of the plurality of resistive memories decreases the ones probability.

In one or more embodiments, the TTRNG also includes a randomness monitor that is configured to monitor the ones probability during a sequence of clock pulses; and a tuning controller that is configured to adjust the ones probability by changing the resistance of one or both of the resistive memories. In one or more embodiments, the randomness monitor includes a digital adder circuit. In one or more embodiments, the randomness monitor includes an analog capacitor. In one or more embodiments, the tuning controller includes a first comparator 124 that compares a signal from the means for monitoring the ones probability to a low threshold value; and a second comparator 126 that compares a signal from the means for monitoring the ones probability to a high threshold value.

In one or more embodiments, the control transistor is connected between the inverter output terminals and ground voltage. In one or more embodiments, at least one of the resistive memories connects a p-type field effect transistor (PFET) of an inverter to logic voltage. In one or more embodiments, each of the resistive memories connects a p-type field effect transistor (PFET) of an inverter to logic voltage. In one or more embodiments, at least one of the resistive memories bypasses a p-type field effect transistor (PFET) of an inverter to logic voltage. In one or more embodiments, the control transistor is connected between the inverter output terminals and logic voltage. In one or more embodiments, at least one of the resistive memories bypasses an n-type field effect transistor (NFET) of an inverter to ground voltage. In one or more embodiments, at least one of the resistive memories connects an n-type field effect transistor (NFET) of an inverter to ground voltage.

According to another aspect, an exemplary method 1100 for tuning a true random number generator (TRNG) includes, at 1102, producing a stream of high and low bits at a node of the TRNG by repeatedly: at 1104, forcing a pair of cross-coupled inverters to a meta-stable voltage state by connecting the cross-coupled inverters to a forcing voltage, wherein the node of the TRNG is a node of the cross-coupled inverters; and at 1106, producing a random bit at the node of the TRNG by exposing the cross-coupled inverters to a random noise while removing the forcing voltage, such that the node returns to one of two stable voltages. The method also includes, at 1108, estimating randomness of the stream at a tuning interval; at 1110, comparing the estimate of randomness to a specification; and at 1112, in response to the estimate of randomness failing the specification, tuning the TRNG by adjusting a resistance of at least one memory cell connected with the cross-coupled inverters.

In one or more embodiments, estimating randomness includes accumulating a sequence of high bits at an adder connected to the node, and comparing the estimate of randomness to a specification includes comparing the accumulated total of high bits to a total number of high and low bits.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A tunable true random number generator (TTRNG) apparatus, comprising:
a clock pulse source;
a logic voltage source;
an output terminal;
a ground terminal;
a plurality of transistors that are connected between the clock pulse source, the logic voltage source, the output terminal, and the ground terminal; and
resistive memory cells that are connected with the plurality of transistors and at least one of the logic voltage source and the ground terminal,
wherein the plurality of transistors are connected such that, at each clock pulse, the plurality of transistors deliver either logic voltage “1” or ground voltage “0” to the output terminal,
wherein the resistive memory cells are connected such that a ones probability of the plurality of transistors delivering “1” to the output terminal can be adjusted by changing the resistances of the resistive memory cells.

2. The apparatus of claim 1, further comprising:
a randomness monitor that is configured to monitor the ones probability during a sequence of clock pulses; and
a tuning controller that is configured to adjust the ones probability for a subsequent sequence of clock pulses by changing the resistance of one or more of the resistive memory cells.

3. The apparatus of claim 2, wherein the randomness monitor comprises:
a digital adder circuit.

4. The apparatus of claim 2, wherein the randomness monitor comprises:
an analog capacitor.

5. The apparatus of claim 2, wherein the tuning controller comprises:
a first comparator that compares a signal from the means for monitoring the ones probability to a low threshold value; and
a second comparator that compares a signal from the means for monitoring the ones probability to a high threshold value.

6. The apparatus of claim 1, wherein the plurality of transistors comprise:
a pair of cross-coupled inverters that have NFET sources connected to ground voltage; and
a control transistor that connects the NFET sources of the cross-coupled inverters to the ground voltage.

7. The apparatus of claim 1, wherein the plurality of transistors comprise:
a pair of cross-coupled inverters that have PFET drains connected to logic voltage; and
a control transistor that connects the PFET drains to the logic voltage.

8. A tunable true random number generator (TTRNG) comprising:
a clock pulse source;
a logic voltage source;
a pair of cross-coupled inverters that each have a p-type field effect transistor (PFET) and an n-type field effect transistor (NFET), with the source of the PFET connected to the drain of the NFET at an inverter output terminal, the drain of the PFET connected to the logic voltage source, the source of the NFET connected to the ground terminal, and the inverter output terminal connected to gates of the other inverter’s PFET and NFET;
a control transistor that is connected to the cross-coupled inverters and to the clock pulse source such that at least one of the inverter output terminals goes to ground voltage on a high clock pulse and at least one of the inverter output terminals goes to logic voltage source on a low clock pulse; and
a plurality of resistive memories that are operatively connected with the pair of cross-coupled inverters such that changing the resistance of one of the plurality of resistive memories increases a ones probability of settling a corresponding one of the inverter output terminals to the high voltage state while changing the resistance of another of the plurality of resistive memories decreases the ones probability.

9. The apparatus of claim 8, further comprising:
a randomness monitor that is configured to monitor the ones probability during a sequence of clock pulses; and
a tuning controller that is configured to adjust the ones probability by changing the resistance of one or both of the resistive memories.

10. The apparatus of claim 9, wherein the randomness monitor comprises:
a digital adder circuit.

11. The apparatus of claim 9, wherein the randomness monitor comprises:
an analog capacitor.

12. The apparatus of claim 8, wherein the control transistor is connected between the inverter output terminals and ground voltage.

13. The apparatus of claim 12, wherein at least one of the resistive memories connects a p-type field effect transistor (PFET) of an inverter to logic voltage.

14. The apparatus of claim 13, wherein each of the resistive memories connects a p-type field effect transistor (PFET) of an inverter to logic voltage.

15. The apparatus of claim 12, wherein at least one of the resistive memories bypasses a p-type field effect transistor (PFET) of an inverter to logic voltage.

16. The apparatus of claim 8, wherein the control transistor is connected between the inverter output terminals and logic voltage.

17. The apparatus of claim 16, wherein at least one of the resistive memories bypasses an n-type field effect transistor (NFET) of an inverter to ground voltage.

18. The apparatus of claim 16, wherein at least one of the resistive memories connects an n-type field effect transistor (NFET) of an inverter to ground voltage.

19. A method for tuning a true random number generator (TRNG), the method comprising:
producing a stream of high and low bits at a node of the TRNG by repeatedly:
forcing a pair of cross-coupled inverters to a meta-stable voltage state by connecting the cross-coupled inverters to a forcing voltage, wherein the node of the TRNG is a node of the cross-coupled inverters; and
producing a random bit at the node of the TRNG by exposing the cross-coupled inverters to a random noise while removing the forcing voltage, such that the node returns to one of two stable voltages;
estimating randomness of the stream at a tuning interval;
comparing the estimate of randomness to a specification; and
in response to the estimate of randomness failing the specification, tuning the TRNG by adjusting a resistance of at least one memory cell connected with the cross-coupled inverters.

20. The method of claim 19, wherein estimating randomness comprises accumulating a sequence of high bits at an adder connected to the node, and comparing the estimate of randomness to a specification comprises comparing the accumulated total of high bits to a total number of high and low bits.
